(19) United States
(12) Patent Application Publication
(10) Pub. No.: US 2006/0203722 A1
(43) Pub. Date: Sep. 14, 2006

(54) System and method for managing performance of mobile terminals via remote diagnostics

(75) Inventor: Paul Oommen, Irving, TX (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: Nokia Corporation, Espoo (FI)

(21) Appl. No.: 11/079,757

(22) Filed: Mar. 14, 2005

(51) Int. Cl. H04L 1/00; G01R 31/08; G06F 11/00; H04Q 7/24

(52) U.S. Cl. 370/229; 370/338

(57) ABSTRACT

A system for managing performance of a terminal includes a service level manager capable of identifying one or more QoS management parameters based upon a service level agreement associated with a selected service. Because the QoS management parameters may differ from layer to layer in a multi-layer protocol stack, the service level manager is also capable of mapping the QoS management parameters to corresponding layer-specific QoS parameters for different protocol layers. Thereafter, the service level manager is capable of downloading, to the terminal, a service level specification (SLS) including the layer-specific QoS parameters. In this regard, the SLS is downloaded to the terminal during provisioning of the selected service, where the service provisioning is performed via an over-the-air (OTA) framework. Thereafter, the QoS experienced by the terminal in effectuating the selected service can then be managed based upon the SLS.

### FIELD OF THE INVENTION

The present invention generally relates to systems and methods of managing performance of network entities, and more particularly relates to systems and methods of managing performance of mobile terminals at least partially operating in a mobile environment.

### BACKGROUND OF THE INVENTION

The development of mobile communication devices and mobile networks has advanced at a rapid rate. At first, analog mobile networks enabled voice communication and simple paging features. Later, digital mobile networks provided more advanced features for voice and data communication, such as encryption, caller identification and short message service (SMS) text messages. More recently, third-generation (3G) mobile IP network technology is being developed to enable users to easily access content rich media, information and entertainment with mobile devices.

In providing the increasing number of features and services available to mobile networks, service providers typically attempt to maintain a minimum level of quality-of-service (QoS) for their users. In this regard, managing the QoS of one or more services provided to mobile networks generally includes the administration of a set of rules that may include one or more value statements and associated actions to be performed. The set of rules is commonly called a profile, policy or service level agreement (SLA). These rules may be a contract between the customer and the network operator or service provider that specifies the QoS, the customer requirements and the cost associated with that service.

Existing techniques for managing the QoS of a mobile user are based on independent performance/QoS management techniques at each layer of a multi-layer protocol stack. For example, network level QoS follows network level procedures, while physical layer QoS management follows a different, independent physical layer protocol. Thus, to improve the performance/QoS management of services provided to mobile users, it would be desirable to develop an end-to-end performance and QoS management framework that integrates or otherwise harmonizes QoS management at different layers of the multi-layer protocol stack.

### SUMMARY OF THE INVENTION

In view of the foregoing background, embodiments of the present invention provide a framework for end-to-end QoS management of services provided to mobile devices. In accordance with embodiments of the present invention, QoS provisioning and management for a service of a terminal can be provided via an over-the air (OTA) framework for the respective terminal. Embodiments of the present invention therefore provide a framework for end-to-end QoS management. Generally, in accordance with embodiments of the present invention, the end-to-end QoS management provisions QoS as part of service provisioning for the underlying service, including defining QoS parameters for different layers requiring management. Then, the QoS management of embodiments of the present invention enables performance monitoring by monitoring the parameters at different layers, including the application, network and/or physical layers, and if so desired, user experience. During effectuation of the respective service, control over QoS can be provided via feedback (e.g., adaptive) algorithms.

The framework for end-to-end QoS management of embodiments of the present invention enhances mobile user experience through application-level QoS, which results in improved perception such as, for example, picture quality, audio quality and/or voice continuity. The framework also enables pricing for a service to be set or otherwise established in accordance with adaptive pricing models instead of fixed models. That is, the framework permits pricing for a service to be established on the basis of utility, or rather the quality of service actually received by the user from the respective service provider. Further, the framework reduces the need to over-provision network resources to terminals effectuating a service, thereby reducing costs incurred by the respective service provider.

In accordance with one aspect of the present invention, a system is provided for managing performance of a terminal. The system includes a service level manager capable of identifying one or more QoS management parameters based upon a service level agreement (SLA), where the SLA is associated with a selected service capable of being effectuated by the terminal. Because the QoS management parameters may differ from layer to layer in a multi-layer protocol stack, the service level manager is also capable of mapping the QoS management parameters to corresponding layer-specific QoS parameters for different protocol layers, such the application, network and physical layers. Thereafter, the service level manager is capable of downloading, to the terminal, a service level specification (SLS) including the layer-specific QoS parameters. In this regard, the SLS is downloaded to the terminal during provisioning of the selected service, where the service provisioning is performed via an over-the-air (OTA) framework, such as an IP-based OTA framework (e.g., IOTA-DM, OMA DM, etc.) or a non-IP-based OTA framework (e.g., CDMA OTASP/OTAPA, etc.). Thus, the system can further include a device management (DM) server capable of performing service provisioning of the selected service at the terminal. The DM server, in turn, can be capable of communicating with the service level manager during the service provisioning to thereby trigger the service level manager to download the SLS to the terminal.

More particularly, the service level manager can be capable of downloading the SLS during OTA service provisioning (OTASP) of the selected service via the OTA framework. Accordingly, the service level manager can be further capable of updating at least one QoS management parameter, mapping the updated QoS management parameters to corresponding updated, layer-specific QoS parameters, and downloading, to the terminal, an updated SLS including the updated, layer-specific QoS parameters. In such instances, in accordance with the OTA framework, the service level manager can be capable of downloading the updated SLS via the OTA framework.

After the SLS is downloaded to the terminal, the QoS experienced by the terminal in effectuating the selected service can then be managed based upon the SLS. For example, the terminal can receive the downloaded SLS, and thereafter store the downloaded SLS in a device management tree of the terminal such that the downloaded SLS is associated with the selected service in the device management tree. Thereafter, the terminal can be at least partially capable of managing the QoS experienced by the terminal based upon the SLS. Thus, the service level manager can be further capable of translating the layer-specific QoS parameters into a format (e.g., IOTA/OMA DM format) and configuration (device description framework—DDF) in accordance with the OTA framework before downloading the layer-specific QoS parameters. Accordingly, the service level manager can be capable of downloading a SLS including the translated layer-specific QoS parameters.

In accordance with other aspects of the present invention, a terminal, method and computer program product for managing performance of a terminal are also provided. Embodiments of the present invention therefore provide a system, terminal, method and computer program product for managing performance of a terminal. In accordance with embodiments of the present invention, performance or QoS of a terminal is capable of being managed via remote diagnostics in a device management framework. In this regard, a service level manager is capable of downloading, to the terminal, QoS parameters by which QoS of the terminal is measured, where the downloaded parameters comprise parameters for a number of different protocol layers and are downloaded via the OTA framework. Embodiments of the present invention therefore enable performance management of the terminal independent of independent performance management mechanisms at each layer of the protocol stack. Embodiments of the present invention provide an integrated mechanism for end-to-end performance management harmonized across various protocol layers. As such, the system and method of embodiments of the present invention solve the problems identified by prior techniques and provide additional advantages.

### BRIEF DESCRIPTION OF THE DRAWINGS

Having thus described the invention in general terms, reference will now be made to the accompanying drawings, which are not necessarily drawn to scale, and wherein:

FIG. 1 is a schematic block diagram of a system for managing performance of one or more terminals, according to one embodiment of the present invention;

FIG. 2 is a schematic block diagram of an entity capable of operating as a network node, in accordance with embodiments of the present invention;

FIG. 3 is a schematic block diagram more particularly illustrating a mobile terminal according to embodiments of the present invention;

FIGS. 4 and 5 are flowcharts illustrating various steps in a method of managing performance of a terminal at least partially via an over-the-air (OTA) framework, in accordance with embodiments of the present invention;

FIG. 6 a functional block diagram of a terminal effectuating a provisioned service in accordance with a service level specification, in accordance with embodiments of the present invention; and

FIG. 7 is a functional block diagram of a terminal and one or more networks controlling QoS of the terminal at different protocol layers, in accordance with embodiments of the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

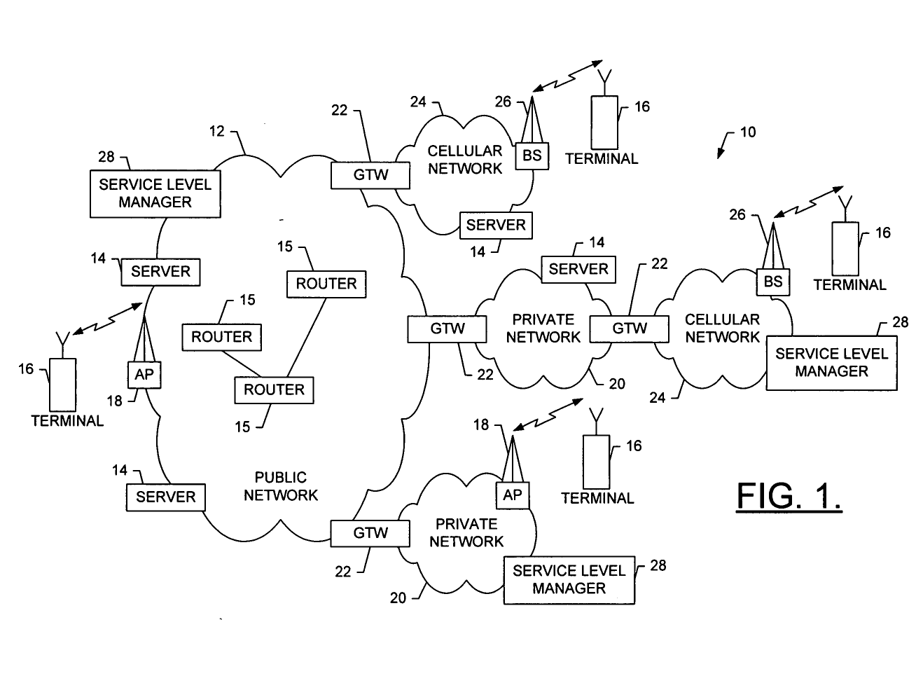

Referring to FIG. 1, an illustration of one type of system that would benefit from the present invention is provided. As shown, the system 10 includes a public network 12, such as a public Internet Protocol (IP) network like the Internet. The public network includes a number of network nodes, each of which typically comprise a processing element such as a server computer, router computer, personal computer, laptop computer or the like. More particularly, the public network can include one or more network nodes comprising server processors 14, workstations or the like (hereinafter individually referred to as a “server”), each of which are capable of communicating within or across the public network. One or more of the servers may operate as a device management (DM) server, as explained below. The public network can also include a number of routers 15 through which communications are passed through the public network. In addition, the pubic network can include one or more network nodes comprising mobile terminals 16, each of which are capable of communicating within or across the public network.

The terminals 16 can comprise, for example, mobile telephones, portable digital assistants (PDAs), pagers, laptop computers, smart cards and other types of electronic systems. To facilitate the terminals accessing the public network, the public network can include one or more wireless access points (AP's) 18, each of which can be coupled to one or more terminals. In this regard, the AP's can comprise access points configured to communicate with the terminal in accordance techniques such as, for example, radio frequency (RF), Bluetooth (BT), infrared (IrDA) or any of a number of different wireless networking techniques, including WLAN techniques. In accordance with embodiments of the present invention, one or more terminals are capable of operating as a client to communicate with one or more servers. It should be appreciated, however, that one or more terminals can additionally, or alternatively, be capable of operating as a server.

In addition to the public network 12, the system 10 can include one or more private networks 20, such as local area networks (LANs). Each private network, like the public network, can include a number of network nodes. Also, like the public network 12, the network nodes of one or more private networks can include one or more servers 14 and, if so desired, one or more routers (not shown). One or more private networks can also, like the public network, include one or more network nodes comprising one or more mobile terminals 16, each of which can be coupled to an AP 18. Further, to facilitate communications between network nodes of the public network and network nodes of the private networks, each private network can further include a gateway processor (GTW) 22 interconnecting the public network and the private network.

The system 10 can also include one or more mobile or cellular networks 24. The cellular networks can comprise one or more of a number of different mobile networks. In this regard, the cellular networks can comprise any of a number of first-generation (1G), second-generation (2G), 2.5G and/or third-generation (3G) cellular networks, and/or any of a number of other cellular networks capable of operating in accordance with embodiments of the present invention. For example, each cellular network can comprise a GSM (Global System for Mobile Communication), IS-136 (Time Domain Multiple Access—TDMA), IS-95 (Code Division Multiple Access—CDMA), or EDGE (Enhanced Data GSM Environment) network. Alternatively, one or more of the cellular networks can comprise GPRS (General Radio Packet Service) or GPRS-based (e.g., Universal Mobile Telecommunications System—UMTS) networks.

Like the public and private networks 12, 20, the cellular networks 24 also include one or more network nodes. In this regard, the network modes of each cellular network can include mobile terminals capable of communicating within and/or across a respective cellular network. More particularly, the cellular networks can include one or more servers 14 and, if so desired, routers (not shown), as with the public and private networks. In addition, the cellular networks can include one or more network nodes comprising terminals 16. To couple each terminal to the cellular network, however, the cellular network includes a base site or base station (BS) 26. As will be appreciated, the BS is a part of the cellular network, which can also include other elements required to operate the cellular network, such as a mobile switching center (MSC) (not shown). Similar to before, to facilitate communications between network nodes of the public and/or private networks and network nodes of the cellular networks, each cellular network can further include a GTW 22 interconnecting the cellular network and a public or private network.

In accordance with embodiments of the present invention, one or more of the mobile terminals 16 of the public network 12, private networks 20, and/or cellular networks 24 are capable of operating as a client to communicate with one or more servers 14 for one or more of a number of different purposes. Alternatively, one or more of the terminals can operate as one or more servers in communication with other terminal(s) operating as client(s). More particularly, then, one or more of the mobile terminals are capable of communicating with one or more servers within the same or a different network, such as to request and thereafter effectuate one or more services provisioned to the terminal. In this regard, to manage the quality of service (QoS) of the service(s) provisioned to the terminal, the network nodes of one or more of the public network, private network(s) and cellular network(s) can also include one or more service level manager's 28, as described in greater detail below.

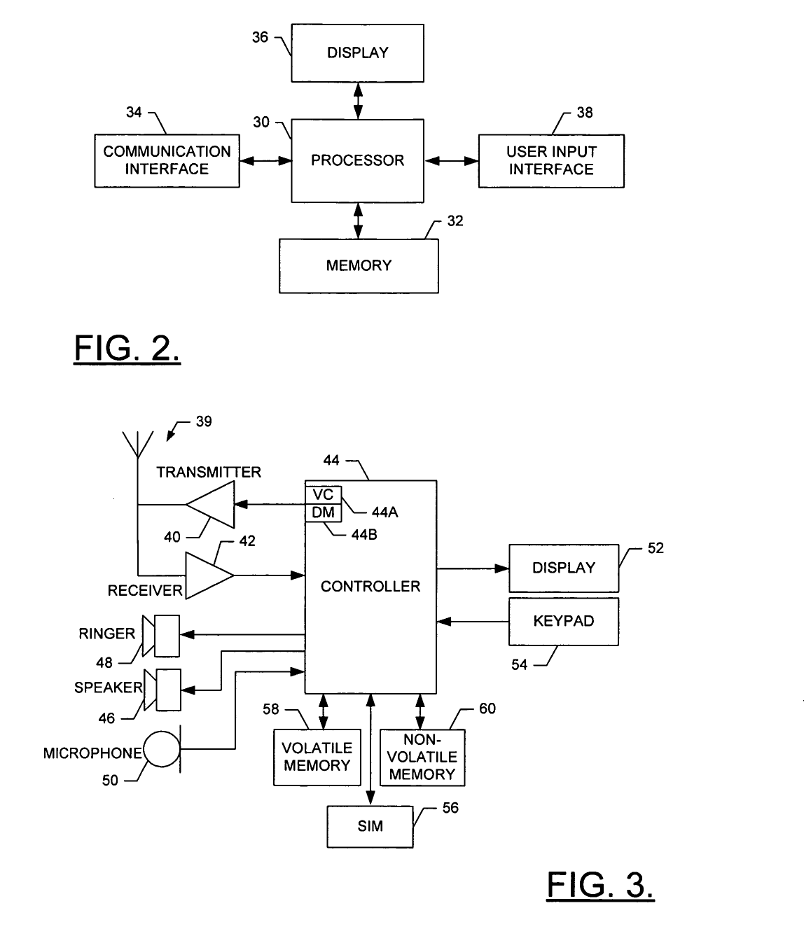

Reference is now made to FIG. 2, which illustrates a block diagram of an entity capable of operating as a network node (e.g., server 14, terminal 16, service level manager 28, etc.) within the public network 12, private network(s) 20 or cellular network(s) 24, in accordance with one embodiment of the present invention. Although shown as separate entities, in some embodiments, one or more entities may support one or more of the network nodes, logically separated but co-located within the entit(ies). For example, a single entity may support a logically separate, but co-located, server and terminal. Also, for example, a single entity may support a logically separate, but co-located server and service level manager, particularly when the server operates as a DM server.

As shown, the entity capable of operating as a network node can generally include a processor 30 connected to a memory 32. The memory can comprise volatile and/or non-volatile memory, and typically stores content, data or the like. For example, the memory typically stores content transmitted from, and/or received by, the entity. Also for example, the memory typically stores software applications, instructions or the like for the processor to perform steps associated with operation of the entity in accordance with embodiments of the present invention.

In addition to the memory 32, the processor 30 can also be connected to at least one interface or other means for displaying, transmitting and/or receiving data, content or the like. In this regard, the interface(s) can include at least one communication interface 34 or other means for transmitting and/or receiving data, content or the like, as well as at least one user interface that can include a display 36 and/or a user input interface 38. The user input interface, in turn, can comprise any of a number of devices allowing the entity to receive data from a user, such as a keypad, a touch display, a joystick or other input device.

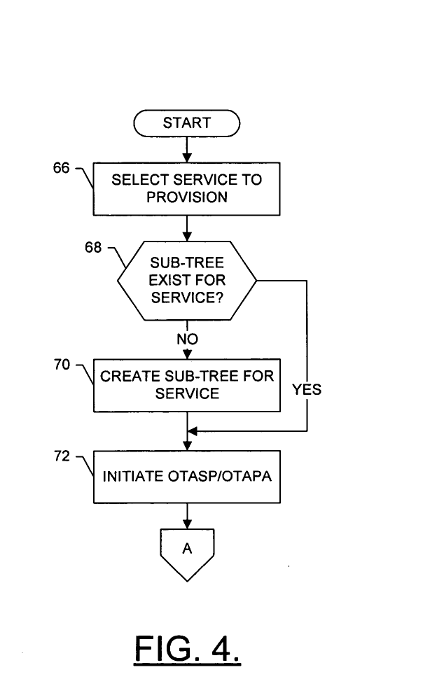

Reference is now made to FIG. 3, which more particularly illustrates one type of terminal 16 that would benefit from embodiments of the present invention. It should be understood, however, that the terminal illustrated and hereinafter described is merely illustrative of one type of terminal that would benefit from the present invention and, therefore, should not be taken to limit the scope of the present invention. While several embodiments of the terminal are illustrated and will be hereinafter described for purposes of example, other types of terminals, such as those indicated above, can readily employ the present invention.

As shown, in addition to an antenna 39, the terminal 16 includes a transmitter 40, a receiver 42, and a controller 44 that provides signals to and receives signals from the transmitter and receiver, respectively. These signals include signaling information in accordance with the air interface standard of the applicable cellular system, and also user speech and/or user generated data. In this regard, the terminal can be capable of operating with one or more air interface standards, communication protocols, modulation types, and access types. More particularly, the terminal can be capable of operating in accordance with any of a number of 1G, 2G, 2.5G and/or 3G cellular networks, and/or any of a number of other cellular networks capable of operating in accordance with embodiments of the present invention. For example, the terminal may be capable of operating in accordance with 2G wireless communication protocols GSM, IS-136 (TDMA) and/or IS-95 (CDMA). Additionally or alternatively, for example, the terminal may be capable of operating in accordance with 2.5G wireless communication protocols GPRS, EDGE or the like. Further, for example, the terminal may be capable of operating in accordance with 3G wireless communication protocols such as UMTS network.

It is understood that the controller 44 includes the circuitry required for implementing the audio and logic functions of the terminal 16. For example, the controller may be comprised of a digital signal processor device, a microprocessor device, and various analog-to-digital converters, digital-to-analog converters, and other support circuits. The control and signal processing functions of the terminal are allocated between these devices according to their respective capabilities. The controller can additionally include an internal voice coder (VC) 44A, and may include an internal data modem (DM) 44B. Further, the controller may include the functionally to operate one or more software programs, which may be stored in memory (described below). For example, the controller may be capable of operating a connectivity program, such as a conventional Web browser. The connectivity program may then allow the terminal to transmit and receive Web content, such as according to HTTP and/or the Wireless Application Protocol (WAP), for example.

The terminal 16 also comprises a user interface including a conventional earphone or speaker 46, a ringer 48, a microphone 50, a display 52, and a user input interface, all of which are coupled to the controller 44. The user input interface, which allows the terminal to receive data, can comprise any of a number of devices allowing the terminal to receive data, such as a keypad 54, a touch display (not shown) or other input device. In embodiments including a keypad, the keypad includes the conventional numeric (0-9) and related keys (#, *), and other keys used for operating the terminal. Although not shown, the terminal can include a battery, such as a vibrating battery pack, for powering the various circuits that are required to operate the terminal, as well as optionally providing mechanical vibration as a detectable output.

Although not shown, the terminal can further include one or more means for locally sharing data with one or more other network nodes, such as AP's 18. The sharing of data, as well as the remote sharing of data, can also be provided according to a number of different techniques. For example, the terminal can include a radio frequency (RF) transceiver capable of sharing data with other radio frequency transceivers, and/or with a Radio Frequency Identification (RFID) transponder tag, as such is known to those skilled in the art. Additionally, or alternatively, the terminal may share data using Bluetooth brand wireless technology developed by the Bluetooth Special Interest Group. Further, for example, the terminal may share data using any of a number of different wireless networking techniques, including WLAN techniques such as IEEE 802.11 techniques or the like.

The terminal 16 can further include memory, such as a subscriber identity module (SIM) 56, a removable user identity module (R-UIM) or the like, which typically stores information elements related to a mobile subscriber. In addition to the SIM, the terminal can include other removable and/or fixed memory. In this regard, the terminal can include volatile memory 58, such as volatile Random Access Memory (RAM) including a cache area for the temporary storage of data. The terminal can also include other non-volatile memory 60, which can be embedded and/or may be removable. The non-volatile memory can additionally or alternatively comprise an EEPROM, flash memory or the like. The memories can store any of a number of pieces of information, and data, used by the terminal to implement the functions of the terminal. For example, the memories can store an identifier, such as an international mobile equipment identification (IMEI) code, international mobile subscriber identification (IMSI) code, terminal integrated services digital network (MSISDN) code (mobile telephone number), Session Initiation Protocol (SIP) address or the like, capable of uniquely identifying the terminal. As explained below, the memories can also store one or more applications capable of operating on the terminal.

A number of nodes (e.g., server 14, terminal 16, etc.) of the system are configured to operate in accordance with a protocol stack, such as the protocol stack provided by the Open Systems Interconnection (OSI) model. As will be appreciated, the protocol stack may be implemented in software, hardware, firmware or combinations of the same. More particularly, the OSI model comprises seven layers, including an application layer, presentation layer, session layer, transport layer, network layer, data link layer and physical layer. The OSI model was developed by the International Organization for Standardization (ISO) and is described in ISO 7498, entitled: The OSI Reference Model, the contents of which are incorporated herein by reference in its entirety. Generally, each layer of the OSI model performs a specific data communications task, a service to and for the layer that precedes it (e.g., the network layer provides a service for the transport layer). The process can be likened to placing a letter in a series of envelopes before it is sent through the postal system. Each succeeding envelope adds another layer of processing or overhead information necessary to process the transaction. Together, all the envelopes help make sure the letter gets to the right address and that the message received is identical to the message sent. Once the entire package is received at its destination, the envelopes are opened one by one until the letter itself emerges exactly as written.

Actual data flow between two nodes (e.g., between terminal 16 and server 14) is from top to bottom in the source node, across the communications line, and then from bottom to top in the destination node. Each time that user application data passes downward from one layer to the next layer in the same node more processing information is added. When that information is removed and processed by the peer layer in the other node, it causes various tasks (error correction, flow control, etc.) to be performed.

As explained in the background section, existing techniques for managing the QoS of a mobile user are based on independent performance/QoS management techniques at each layer of the multi-layer protocol stack. For example, network level QoS follows network level procedures, while physical layer QoS management follows a different, independent physical layer protocol. Embodiments of the present invention therefore provide an end-to-end performance and QoS management framework that integrates or otherwise harmonizes QoS management at different layers of the multi-layer protocol stack. The end-to-end QoS management framework of embodiments of the present invention defines a set of high level parameters that can thereafter be mapped or otherwise translated to the different levels of the multi-level protocol stack of the respective terminals. The parameters for the different levels can then be provided to the respective terminals via one or more over-the-air (OTA) service provisioning techniques. Accordingly, the parameters for the different levels can be managed for the respective terminals via one or more OTA techniques.

The information stored in the terminal 16 that can be manipulated by actions over a respective network (e.g., public network 12, private network 20, cellular network, 24, etc.) can be organized by the terminal in a hierarchical management tree, also referred to as a device management tree. In this regard, the device management tree can organize available information in the terminal as a hierarchical tree structure where the information can be uniquely addressed with a uniform resource identifier (URI) based upon the location of the information in the device management tree. Each addressed piece of information within the device management tree can, in turn, include a set of properties, such as an access control list (ACL), a name, a type, a version number and a time stamp. Such a device management tree is described in further detail in Open Mobile Alliance (OMA) standard specification SyncML Device Management Tree and

### DESCRIPTION

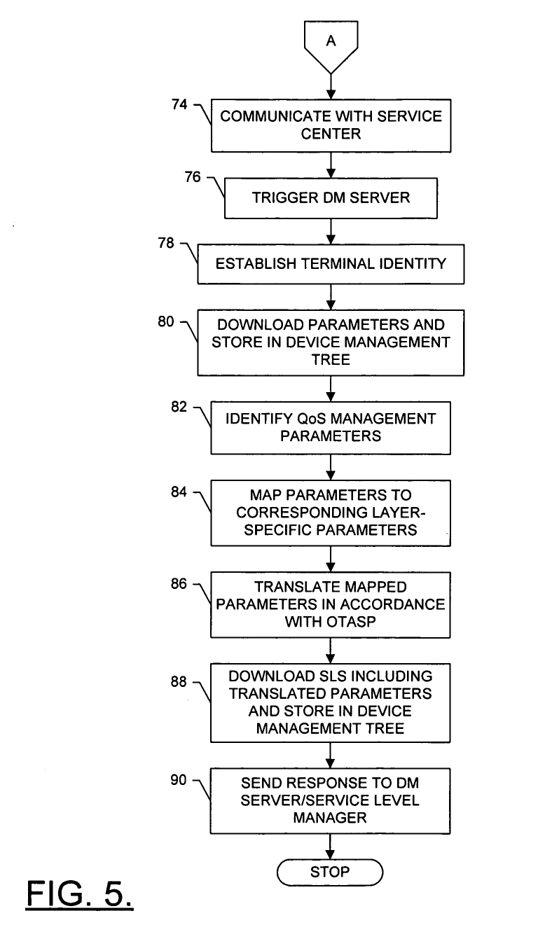

In accordance with one embodiment of the present invention, managing performance of the terminal 16 includes over-the-air service provisioning (OTASP) to enable a service or feature of the terminal, such as to activate the terminal for operation in the cellular network 24. Referring to FIG. 4, before performing the OTASP, a service to be provisioned is selected, as shown in block 66. Once the service has been selected, the terminal determines whether a sub-tree in the device management tree includes the selected service, as shown in block 68. If a sub-tree in the device management tree does not exist for the selected service, the terminal establishes such a sub-tree and labels a root of the sub-tree with an identifier (ID) associated with the service, as illustrated in block 70. In the device management tree, parameters required or otherwise utilized to effectuate the selected service can then be organized underneath the service ID and, thus, associated with the selected service in the tree, as explained below.

In addition to establishing a node for the service in the device management tree of the terminal 16, managing performance of the terminal includes initiating OTASP, as shown in block 72 of FIG. 4. Typically, OTASP can be initiated at one of two ends of the system, either at the terminal or at the respective access network. In this regard, the terminal initiated method allows the terminal user to select a service provider, to activate the terminal to the selected service and to update information stored in the terminal for effectuating the selected service. In contrast, the network-initiated procedure, also known as over-the-air parameter administration (OTAPA), allows the service provider to update information stored in the terminal for effectuating the selected service. In this regard, OTAPA is also built upon the over-the-air programming protocol and methods that support OTASP.

As explained below, performance of the terminal is managed in accordance with an OTA framework. It should be understood, however, that terminal performance can be managed in accordance with any of a number of OTA frameworks. Such an OTA framework includes, for example, an IP-based OTA framework, such as IOTA-DM provided by the 3GPP2 standard specification IP Based Over-the-Air Device Management (IOTA-DM) for cdma2000 Systems or OMA-DM provided by the OMA standard specification SyncML Device Management Protocol. Another such OTA framework comprises, for example, a non-IP-based OTA framework (non-IP OTA-DM) framework, such as CDMA OTASP/OTAPA provided by the 3GPP2 standard specification C.S0016-C entitled: Over-the-Air Service Provisioning of Mobile Stations in Spread Spectrum Standards. And yet another such OTA framework comprises, for example, the Simple Network Management Protocol (SNMP) framework.

With reference to FIG. 5, user-initiated OTASP typically includes communicating with a service center of a provider of the selected service, as shown in block 74. The service provider can be selected in any one of a number of different ways. For example, the service provider can be selected by programming the terminal 16 to attempt OTASP with one or more particular service providers, or by programming the terminal to scan for multiple service providers and thereafter presenting the user with a list from which to choose a service provider. Although not shown, the service center can be coupled to an AP 16 or BS 26 of the respective network. In this regard, it will be appreciated that the origination call can be transferred to the service center as a service request via the base AP or BS.

Upon receipt of the service request, the service center triggers a respective DM server (e.g., server 14) to begin a management session with the terminal 16, as shown in block 76. In response to the trigger from the service center, the DM server initiates communication with the terminal to thereby begin the management session. After communication has been established with the terminal, the terminal identifies itself to the DM server, as shown in block 78. By identifying itself, the terminal establishes a unique identity with the DM server and gives the DM server information about the terminal capabilities, as well as the information stored by the terminal. Thereafter, the DM server assigns, establishes or otherwise sets a number of parameters for the terminal. For example, when the DM server is activating the terminal for operation in the cellular network 24, the DM server can assign a Mobile Identification Number (MIN) to the terminal, as well as establish an authentication key (“A-Key”) and Number Assignment Module (NAM) parameters, including a preferred mode of operation (analog or digital), shared secret data (SSD), and roaming information such as a “Preferred Roaming List.” The parameters can be formatted and configured in any of a number of different manners. For example, the parameters can be formatted an extensible markup language (XML) format, such as that in accordance with a management protocol provided by IOTA-DM, OMA DM or the like. Further, the parameters can be configured in accordance with a IOTA/OMA device description framework (DDF), such as that included in the OMA standard specification SyncML Device Management Tree and Description. Irrespective of how the parameters are formatted and configured, however, as or after the parameters are assigned, the parameters are downloaded to the terminal from the DM server (e.g., server 14), as shown in block 80. Upon receipt of each parameter, the terminal 16 stores the parameter in the device management tree such that the parameter is associated with the selected service in the device management tree. Also, an access control list (ACL) associated with each parameter can be established or updated accordingly, as will be appreciated by those skilled in the art.

In addition to downloading the parameters required to effectuate the selected service to the terminal 16, before, after or as the aforementioned parameters are downloaded to the terminal during OTASP, the DM server (e.g., server 14) can communicate with a respective service level manager 28. The DM server is thereby capable of triggering the service level manager to provide or otherwise download, to the terminal, one or more quality-of-service (QoS) management parameters for maintaining a required quality of the selected service. In this regard, in provisioning a selected service to the terminal, the terminal user and service provider typically agree upon a requisite QoS and price for the service, where the agreed-upon QoS and price are typically embodied in a service level agreement (SLA). Generally, then, the SLA can be viewed as a contract between the service provider and the user that defines QoS guarantees and prices, and penalties if the service provider cannot meet the specified QoS. That is, the QoS corresponds to the goodness (quality) with which a certain operation (service) is performed. For example, certain services such as multimedia applications or transatlantic phone calls may require guarantees about accuracy, dependability and the rate of transmission performed. The QoS is the spectrum of services that measure, improve and to some extent guarantee in advance network transmission rates, error rates, and other characteristics.

More particularly, the service level manager 28 identifies one or more QoS management parameters based upon the SLA established for the selected service, as shown in block 82. For example, the service level manager can identify QoS management parameters such as one or more minimum values and/or ranges related to with network bandwidth, variation in packet delay, network latency/jitter, data packet loss, network availability and/or reliability. As will be appreciated, however, a number of the QoS management parameters can have different values or ranges for different layers of the multi-layer protocol stack of the terminal. For example, the bandwidth parameter can comprise a video frame rate at the application layer, but comprise a transmission bit rate at the network (e.g., IP) layer. Thus, in accordance with embodiments of the present invention, one or more identified QoS management parameters are mapped to corresponding QoS management parameters for different layers of the multi-layer protocol stack, as shown in block 84. In one embodiment, for example, the identified QoS management parameters are mapped to corresponding QoS management parameters for the application layer, transport/network layer and physical layer. These QoS management parameters can be more particularly referred to as application parameters (i.e., application layer parameters), network parameters (i.e., transport/network layer parameters) and bearer parameters (i.e., physical layer parameters).

After mapping the QoS management parameters to different layers of the multi-layer protocol stack, the resulting parameters, including the application, network and bearer parameters, can be downloaded to the terminal 16. Before downloading the mapped parameters to the terminal, however, the mapped parameters can be translated or otherwise formatted and configured in a manner similar to the parameters downloaded from the DM server to the terminal, that is, formatted in accordance with the IOTA/OMA DM protocol and configured in accordance with the IOTA/OMA DM DDF, as shown in block 86. The service level manager 28 can then download the translated parameters, collected into a service level specification (SLS), to the terminal 16, as shown in block 88. The service level manager can download the translated parameters directly to the terminal, such as by initiating communication with the terminal to thereby begin another management session. Alternatively, the service level manager can download the translated parameters indirectly to the terminal via the DM server (e.g., server 14), and thus, the management session of the DM server. Irrespective of how the SLS is downloaded to the terminal 16, however, the terminal stores the SLS in the device management tree such that the SLS is associated with the selected service in the device management tree, such as in a manner similar to before.

After successful storage of one or more of the QoS management parameters and/or SLS, the terminal 16 transmits one or more responses to the source of the respective parameters, such as the DM server (e.g., server 14) or the service level manager, acknowledging successful parameter transfer, as shown in block 90. The response(s) can then be passed by the respective node to the service center of the service provider, either directly or indirectly (e.g., service level manager via the DM server). As suggested above, after each parameter has been downloaded, the DM server/service level manager determines whether to download more parameters to the terminal. If more parameters are to be downloaded, the DM server/service level manager downloads each parameter as before, with the terminal responding as before. If no more parameters are to be downloaded, however, the DM server/service level manager terminates the management session of the terminal, as shown in block 100.

After OTASP, the terminal 16 is thus enabled to effectuate the selected service. Subsequent to the initial OTASP, the service center may desire to update some of the parameters previously downloaded to the terminal. Thus, the service center initiates an OTAPA session. It will be appreciated that the OTAPA session proceeds just as the OTASP session with the exception that the service center initiates OTAPA. Thus, OTAPA begins with the carrier service center triggering the DM server (e.g., server 14) or service level manager 28 to initiate a device management session. The device management session then proceeds as before to update the parameters previously downloaded to the terminal.

As will be appreciated, the selected service can be entirely and directly provided by a single service provider, or one or more components of the service can be outsourced by the service provider to another entity. As a typical mobile user is mostly concerned with the availability and quality of the end-to-end service, such outsourcing desirably occurs in a manner transparent to the mobile user. Thus, whereas the OTASP and OTAPA described herein are performed from a single service center, DM server (e.g., server 14) and service level manager 28, the OTASP and/or OTAPA can equally be performed by more than one service center, DM server and/or service level manager. Even in such instances, however, the selected service is typically provisioned and defined to include a requisite QoS and price embodied in a single SLA.

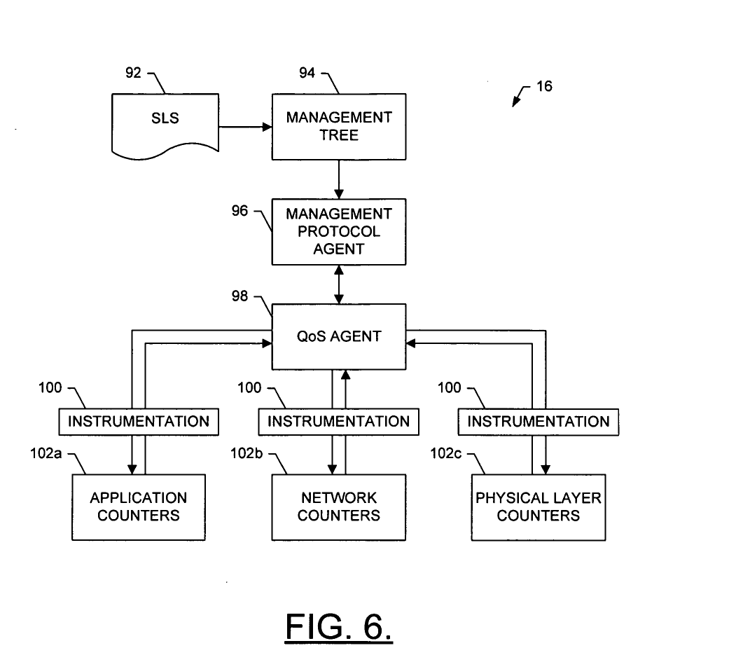

Irrespective of exactly how the OTASP and OTAPA are performed, the terminal 16 is capable of at least partially effectuating or otherwise performing the selected service. Reference is now made to FIG. 6, which illustrates a functional block diagram of a terminal effectuating a provisioned service in accordance with a SLS 92 stored or otherwise included in a device management tree 94 of the terminal. As shown and described herein, the terminal and other nodes of the networks of the system each include a number of functional elements. It should be understood that the functional elements can be embodied in any of a number of different manners, including software, firmware and/or software, without departing from the spirit and scope of the present invention.

As shown in FIG. 6, the terminal 16 can include a management protocol agent 96 for implementing the management protocol (e.g., IOTA/OMA DM, CDMA OTASP/OTAPA, etc.) of the SLS 92 stored in the management tree 94. The management protocol agent can also send management commands to, and/or receive management from, one or more of the networks 12, 20, 24. In communication with the management protocol agent, a QoS agent 98 of the terminal operates on the basis of management commands to at least partially monitor the QoS experienced by the terminal. For example, the QoS agent can receive a management command provisioning the QoS for the selected service, which is defined by the SLS. In response, the QoS agent configures instrumentation 100 and counters 102 (e.g., application counters 102a, network counters 102b, physical layer counters 102c) for measuring the QoS management parameters for the different layers of the multi-layer protocol stack for effectuating the selected service.

The instrumentation 100 and counters 102 are capable of determining whether the QoS experienced by the terminal 16 satisfies the SLS for the specified protocol layers by monitoring conditions of the terminal and/or network(s) 12, 20, 24 in effectuating the selected service. As a result of the information obtained by the instrumentation and counters, actions may be triggered within the terminal and/or network(s). Such actions may include providing resources to effectuate the selected service when the available QoS is within that specified by the SLS, or altering provided resources to bring the experienced QoS within that specified by the SLS. Thus, the instrumentation and counters may be used to determine if and/or when the mobile user is being served according to the underlying SLA for the selected service. For example, the network counter 102b and respective instrumentation can measure the transmission bit rate at the network (e.g., IP) layer, and compare the measured bit rate to a corresponding QoS management parameter in the SLS. Then, if the mobile user cannot be served, or is not being served, according to the underlying SLA, the QoS agent 98 can report the measurements to the node(s) (including the terminal itself), or more particularly the functional element(s) of the node(s), capable of providing resources or altering provided resources affecting the respective layer(s), such that the respective node(s) can bring the measured QoS within that defined by the SLS.

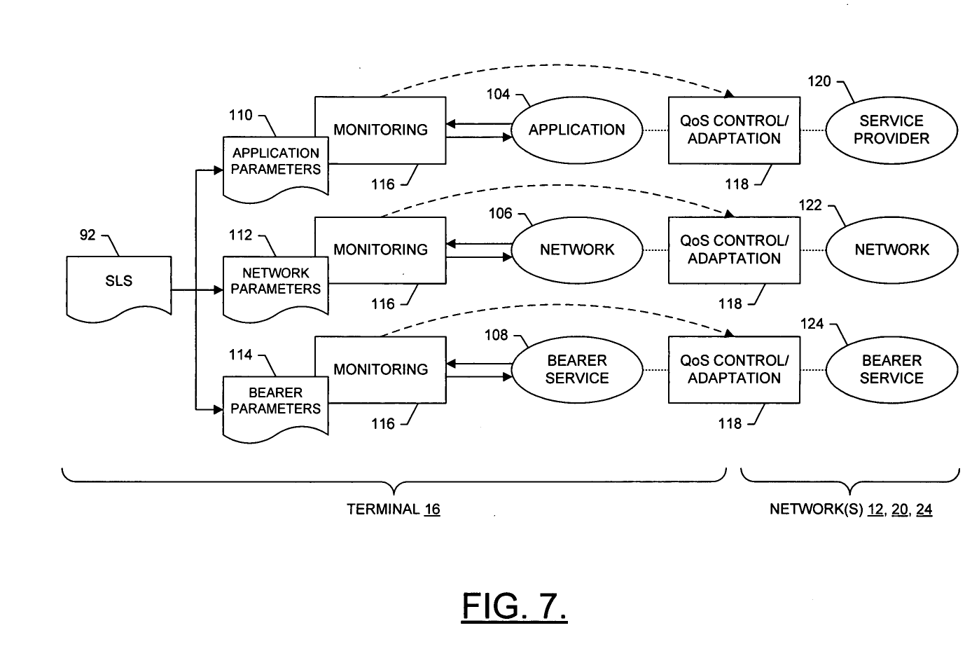

Reference is now accordingly made to FIG. 7, which illustrates a functional block diagram of a terminal 16 and network(s) 12, 20 and 24 controlling QoS at different protocol layers, including the application layer 104, network layer 106 and physical layer 108 (i.e., bearer) level. As shown and explained above, for example, the provisioned SLS 92 includes application parameters 110, network parameters 112 and bearer parameters 114. One or more monitoring functions 116 (e.g., management protocol agent 96, QoS agent 98, instrumentation 100 and application counters 102) monitor the QoS management parameters based upon measurements from respective protocol layers.

Based upon such monitoring, the monitoring function(s) can report the measured QoS parameters to one or more QoS control/adaptation functions 118. The QoS control/adaptation functions can be implemented by the terminal. Alternatively, one or more of the QoS control/adaptation functions can be implemented by the network(s) 12, 20, 24, or more particularly the provider (e.g., service provider 120, network provider 122, bearer service 124) of resources within the respective network(s). In turn, the QoS control/adaptation functions can provide resources for the respective protocol layer, or alter already provided resources, to satisfy the QoS defined by the SLS.

As described above, the QoS management parameters are mapped and translated by a service level manager 28 (see FIG. 5, blocks 84, 86). It should be understood, however, that all or a portion of the mapping and/or translating operations can alternatively be performed by one or more other network nodes. For example, the terminal 16 can itself be configured to map one or more QoS management parameters to corresponding layer-specific parameters for one or more layers. Additionally or alternatively, the terminal can be configured to translate one or more mapped QoS management parameters into a format and configuration consistent with the device management framework over which the QoS management parameters are provisioned to the terminal.

Also, as described above, the mapped QoS management parameters can be formatted in accordance with the IOTA/OMA DM protocol and configured in accordance with the IOTA/OMA DM DDF. Generally, the format and configuration of the mapped QoS management parameters are consistent with the OTA framework via which the OTASP/OTAPA steps are performed, and accordingly the OTA framework via which the translated QoS management parameters are provisioned to the terminal. Thus, it should be understood that the mapped QoS management parameters can be formatted and configured in accordance with any of a number of other OTA frameworks, without departing from the spirit and scope of the present invention. As indicated above, such an OTA framework includes, for example, an IP-based OTA framework (e.g., IOTA/OMA-DM) or a non-IP-based OTA framework (e.g., CDMA OTASP/OTAPA). Another such OTA framework comprises, for example, the Simple Network Management Protocol (SNMP) framework.

According to one aspect of the present invention, all or a portion of the system of the present invention, such all or portions of one or more network nodes including the terminal 16, DM server (e.g., server 14) and/or service level manager 28, generally operates under control of a computer program product. The computer program product for performing the methods of embodiments of the present invention includes a computer-readable storage medium, such as the non-volatile storage medium, and computer-readable program code portions, such as a series of computer instructions, embodied in the computer-readable storage medium.

In this regard, FIGS. 4, 5, 6 and 7 are flowcharts and functional block diagrams of methods, systems and program products according to the invention. It will be understood that each block or step of the flowcharts, and combinations of blocks in the flowcharts, can be implemented by computer program instructions. These computer program instructions may be loaded onto a computer or other programmable apparatus to produce a machine, such that the instructions which execute on the computer or other programmable apparatus create means for implementing the functions specified in the flowcharts' block(s) or step(s). These computer program instructions may also be stored in a computer-readable memory that can direct a computer or other programmable apparatus to function in a particular manner, such that the instructions stored in the computer-readable memory produce an article of manufacture including instruction means which implement the function specified in the flowcharts' block(s) or step(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the flowcharts' block(s) or step(s).

Accordingly, blocks or steps of the flowcharts support combinations of means for performing the specified functions, combinations of steps for performing the specified functions and program instruction means for performing the specified functions. It will also be understood that each block or step of the flowcharts, and combinations of blocks or steps in the flowcharts, can be implemented by special purpose hardware-based computer systems which perform the specified functions or steps, or combinations of special purpose hardware and computer instructions.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

What is claimed is:

1. A system for managing performance of a terminal, the system comprising:
a service level manager capable of identifying at least one quality-of-service (QoS) management parameter based upon a service level agreement (SLA), the SLA being for a selected service capable of being effectuated by the terminal,
wherein the service level manager is also capable of mapping the QoS management parameters to corresponding layer-specific QoS parameters for different layers of a multi-layer protocol stack,
wherein the service level manager is also capable of downloading, to the terminal, a service level specification (SLS) including the layer-specific QoS parameters such that a QoS experienced by the terminal is capable of being managed based upon the SLS, and
wherein the SLS is downloaded to the terminal during provisioning of the selected service, the service provisioning being performed via an over-the-air (OTA) framework.

2. A system according to claim 1, wherein the service level manager is capable of mapping the QoS management parameters to corresponding layer-specific QoS parameters for at least an application layer, a network layer and a physical layer.

3. A system according to claim 1 further comprising:
a terminal capable of receiving the downloaded SLS, and thereafter storing the downloaded SLS in a device management tree of the terminal such that the downloaded SLS is associated with the selected service in the device management tree,
wherein the terminal is at least partially capable of managing the QoS experienced by the terminal based upon the SLS.

4. A system according to claim 1, wherein the service level manager is further capable of translating the layer-specific QoS parameters into a format and configuration in accordance with the OTA framework before downloading the layer-specific QoS parameters, and
wherein the service level manager is capable of downloading a SLS including the translated layer-specific QoS parameters.

5. A system according to claim 1 further comprising:
a device management (DM) server capable of performing service provisioning of the selected service at the terminal, wherein the DM server is capable of communicating with the service level manager during the service provisioning to thereby trigger the service level manager to download, to the terminal, the SLS.

6. A system according to claim 1, wherein the service level manager is capable of downloading the SLS via an Internet Protocol (IP)-based OTA framework.

7. A system according to claim 6, wherein the service level manager is capable of downloading the SLS via an IOTA-DM framework.

8. A system according to claim 6, wherein the service level manager is capable of downloading the SLS via an OMA-DM framework.

9. A system according to claim 1, wherein the service level manager is capable of downloading the SLS via a CDMA OTASP/OTAPA framework.

10. A terminal comprising:
a memory device including a device management tree capable of storing a service level specification (SLS) such that the SLS is associated with a selected service in the device management tree, and such that a quality of service (QoS) experienced by the terminal is capable of being managed based upon the SLS,
wherein the SLS includes layer-specific QoS parameters for different layers of a multi-layer protocol stack, the layer-specific QoS parameters generated by mapping at least one QoS management parameter identified based upon a service level agreement (SLA) for the selected service, and
wherein the device management tree is capable of storing the SLS during provisioning of the selected service, the service provisioning being performed via an over-the-air (OTA) framework.

11. A terminal according to claim 10, wherein the device management tree is capable of storing a SLS including layer-specific QoS parameters for at least an application layer, a network layer and a physical layer.

12. A terminal according to claim 10, wherein the device management tree is capable of storing a SLS including translated layer-specific QoS parameters, the layer-specific QoS parameters having been translated into a format and configuration in accordance with the OTA framework.

13. A terminal according to claim 10, wherein the device management tree is capable of storing the SLS during service provisioning via an IOTA-DM framework.

14. A terminal according to claim 10, wherein the device management tree is capable of storing the SLS during service provisioning via an OMA-DM framework.

15. A terminal according to claim 10, wherein the device management tree is capable of storing the SLS during service provisioning via an CDMA OTASP/OTAPA framework.

16. A method of managing performance of a terminal, the method comprising:
providing a service level agreement (SLA) for a selected service capable of being effectuated by the terminal;
identifying at least one quality-of-service (QoS) management parameter based upon the SLA;
mapping the QoS management parameters to corresponding layer-specific QoS parameters for different layers of a multi-layer protocol stack; and
downloading, to the terminal, a service level specification (SLS) including the layer-specific QoS parameters such that a QoS experienced by the terminal is capable of being managed based upon the SLS,
wherein the SLS is downloaded to the terminal during provisioning of the selected service, the service provisioning being performed via an over-the-air (OTA) framework.

17. A method according to claim 16, wherein the mapping step comprises mapping the QoS management parameters to corresponding layer-specific QoS parameters for at least an application layer, a network layer and a physical layer.

18. A method according to claim 16, wherein the downloading step comprises downloading the SLS such that the terminal is capable of storing the downloaded SLS in a device management tree of the terminal such that the downloaded SLS is associated with the selected service in the device management tree.

19. A method according to claim 16 further comprising:
translating the layer-specific QoS parameters into a format and configuration in accordance with the OTA framework before downloading the layer-specific QoS parameters,
wherein the downloading step comprises downloading a SLS including the translated layer-specific QoS parameters.

20. A method according to claim 16, wherein the downloading step comprises downloading the SLS during service provisioning via an IOTA-DM framework.

21. A method according to claim 16, wherein the downloading step comprises downloading the SLS during service provisioning via an OMA-DM framework.

22. A method according to claim 16, wherein the downloading step comprises downloading the SLS during service provisioning via a CDMA OTASP/OTAPA framework.

23. A computer program product for managing performance of a terminal, the computer program product comprising at least one computer-readable storage medium having computer-readable program code portions stored therein, the computer-readable program code portions comprising:
a first executable portion for providing a service level agreement (SLA) for a selected service capable of being effectuated by the terminal;
a second executable portion for identifying at least one quality-of-service (QoS) management parameter based upon the SLA;
a third executable portion for mapping the QoS management parameters to corresponding layer-specific QoS parameters for different layers of a multi-layer protocol stack; and
a fourth executable portion for downloading, to the terminal, a service level specification (SLS) including the layer-specific QoS parameters such that a QoS experienced by the terminal is capable of being managed based upon the SLS,
wherein the fourth executable portion is adapted to download the SLS to the terminal during provisioning of the selected service, the service provisioning being performed via an over-the-air (OTA) framework.

24. A computer program product according to claim 23, wherein the third executable portion is adapted to map the QoS management parameters to corresponding layer-specific QoS parameters for at least an application layer, a network layer and a physical layer.

25. A computer program product according to claim 23, wherein the fourth executable portion is adapted to download the SLS such that the terminal is capable of storing the downloaded SLS in a device management tree of the terminal such that the downloaded SLS is associated with the selected service in the device management tree.

26. A computer program product according to claim 23 further comprising:
a fifth executable portion for translating the layer-specific QoS parameters into a format and configuration in accordance with the framework before downloading the layer-specific QoS parameters,
wherein the fourth executable portion is adapted to download a SLS including the translated layer-specific QoS parameters.

27. A computer program product according to claim 23, wherein the fourth executable portion is adapted to download the SLS during service provisioning via an IOTA-DM framework.

28. A computer program product according to claim 23, wherein the fourth executable portion is adapted to download the SLS during service provisioning via an OMA-DM framework.

29. A computer program product according to claim 23, wherein the fourth executable portion is adapted to download the SLS during service provisioning via a CDMA OTASP/OTAPA framework.
